(19) United States
(12) Patent Application Publication
(10) Pub. No.: US 2009/0194875 A1
(43) Pub. Date: Aug. 6, 2009

(54) HIGH PURITY Cu STRUCTURE FOR INTERCONNECT APPLICATIONS

(75) Inventors: Chih-Chao Yang, Glenmont, NY (US); Daniel C. Edelstein, White Plains, NY (US)

Correspondence Address: INTERNATIONAL BUSINESS MACHINES CORPORATION;DEPT. 18G, BLDG. 321-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 12/023,318

(22) Filed: Jan. 31, 2008

(51) Int. Cl. H01L 23/48; H01L 21/4763

(52) U.S. Cl. 257/751; 438/627; 257/E21.495; 257/E23.01

(57) ABSTRACT

A structure and method of forming a high purity copper structure for interconnect applications is described. The structure includes a patterned dielectric material and at least one Cu-containing conductive material having an upper surface embedded within the dielectric material; and a diffusion barrier and a noble metal liner separating the patterned dielectric material from the at least one Cu-containing conductive material; where the Cu-containing conductive material having high purity, C<10 ppm, Cl<10 ppm, S<10 ppm, and uniform impurity. A method of fabricating the interconnect structure is also described. The method includes providing an initial interconnect structure that includes a dielectric having at least one opening; forming a diffusion barrier layer on all exposed surfaces; forming a noble metal layer on the diffusion barrier layer; forming a Cu containing layer on the noble metal layer; and completely filling the at least one opening with the Cu containing layer.

### BACKGROUND OF THE INVENTION

1. Technical Field

The present disclosure relates generally to interconnect structures formed in semiconductor devices. In particular, the present disclosure relates to a structure and methods of forming a high purity Cu structure for interconnect applications.

2. Description of Related Art

Integrated circuit chips typically include two or more levels of conductive lines which are vertically spaced apart and separated by intermediate insulating layers. Interconnections are formed between the levels of conductive lines in the chip for providing, for example, high wiring density and good thermal performance. The interconnections are formed by means of lines and vias which are etched through the insulating layers separating the levels. The lines and vias are then filled with a conductive material or metal (e.g. Copper) to form interconnect elements (i.e. via studs).

One preferred method of providing Copper interconnects is the damascene process. A typical damascene process for producing a multilevel structure would include: a blanket deposition of a dielectric material; pattering of the dielectric material to form openings; deposition of a conductive material onto the substrate in sufficient thickness to fill the openings; and removal of excessive conductive material from the substrate surface using a chemical reactant-based process, mechanical methods, or combine chemical-mechanical polishing techniques. Currently the conductive material is typically deposited using electrical-chemical plating (ECP). Other deposition methods are also used, for example, chemical vapor deposition (CVD), evaporation and sputtering.

Thus, a typical interconnect element includes metal vias running perpendicular to the semiconductor substrate and metal lines running parallel to the semiconductor substrate. This process results in multiple levels of conductor wiring interconnection patterns, having individual levels connected by via studs and operating to distribute signals among the various circuits on the chip.

Copper fill of a feature such as a trench or via using ECP tends to create platting voids in the filled opening as an over-hang from a Cu seed grow to touch each other. This is particularly true with regard to high aspect ratio features. However, the requirement of a seeding layer creates a great challenge for good gap-fill quality (i.e. void free). Furthermore, contaminants from the deposition source are frequently found in the deposited conductive material. Although evaporation is successful in covering shallow features, it is generally not practical for the filling high aspect ration features.

As the feature size of semiconductor patterned metal features has become increasingly smaller, the danger of trapping void spaces within the copper fill volume during the ECP process has increased. Therefore, a need exist for a novel a structure and methods of forming a high purity Cu structures for interconnect applications which overcomes the shortcomings of the prior art and which is compatible with existing integration schemes.

### SUMMARY OF THE INVENTION

The present disclosure is directed to a structure and methods of forming interconnect structures. In one embodiment, an interconnect structure is described. The structure includes a patterned dielectric material and at least one Cu-containing conductive material having an upper surface embedded within the dielectric material; and a diffusion barrier and a noble metal liner separating the patterned dielectric material from the at least one Cu-containing conductive material; where the Cu-containing conductive material having uniform impurity. In one embodiment, the Cu-containing conductive material includes Sulfur containing impurity less than about 10 ppm, Carbon containing impurity less than about 10 ppm, and Chlorine, containing impurity less than about 10 ppm. The diffusion barrier is formed on the patterned dielectric layer, and the noble metal liner is formed on the diffusion barrier. The diffusion barrier is selected from the group consisting of Ta(N), Ti(N), W(N) and alloys thereof. The noble metal liner is selected from the group consisting of Ru, Ir, Rh, Pt, Co and alloys thereof. In one particular embodiment, an upper surface of the at least one Cu-containing conductive material is substantially coplanar with the surface layer of the dielectric material. The interconnect structure further includes a dielectric capping layer located atop the dielectric material and the at least one Cu-containing conductive material.

In another embodiment, the interconnect structure includes a patterned dielectric material and at least one Cu-containing conductive material having an upper surface embedded within the dielectric material; and a diffusion barrier and a noble metal liner separating the patterned dielectric material from the at least one Cu-containing conductive material; and the Cu-containing conductive material having NON-uniform impurity. In this particular embodiment, the Cu-containing conductive material includes a higher impurity levels at top part of the structure, but lower impurity levels at bottom part of the structure. In addition the top part of the Cu-containing conductive material having Sulfur containing impurity higher than about 10 ppm, Carbon-containing impurity higher than 10 ppm, and Chlorine, containing impurity higher than about 10 ppm. Moreover, the bottom part of the Cu-containing conductive material includes Sulfur containing impurity less than about 10 ppm, Carbon containing impurity less than about 10 ppm, and Chlorine, containing impurity less than about 10 ppm. The interconnect structure further includes a dielectric capping layer located atop the dielectric material and the at least one Cu-containing conductive material.

In yet another embodiment, a method of fabricating an interconnect structure is described. The method includes providing an initial interconnect structure that includes a dielectric having at least one opening; forming a diffusion barrier layer on all exposed surfaces; forming a noble metal layer on the diffusion barrier layer; forming a Cu containing liner layer on the noble metal layer; and completely filling the at least one opening with the Cu containing liner layer. In one embodiment, the providing the initial interconnect structure includes a via opening, a line opening, and both a via and a line opening; and the forming a diffusion barrier layer and the forming a noble metal layer are being compatible with PVD, CVD, and ALD techniques. In addition, the forming a Cu containing liner layer is being compatible with PVD technique. A Cu containing target used for the PVD deposition technique contains Sulfur containing impurity less than about 10 ppm, Carbon containing impurity less than 10 ppm, and Chlorine, containing impurity less than about 10 ppm. In one particular embodiment, the completely filling the at least one opening with the Cu containing liner layer includes thermal treating, heating, and reflowing of the Cu containing liner layer in an hydrogen-containing ambient. The thermal treating is performed at a temperature from about 100° C. to about 450° C. The hydrogen-containing ambient includes from about 2 to about 100% hydrogen.

In yet another embodiment, a method of fabricating an interconnect structure is described. The method includes providing an initial interconnect structure that includes a dielectric having at least one opening; forming a diffusion barrier layer on all exposed surfaces; forming a noble metal layer on the diffusion barrier layer; forming a Cu containing liner layer on the noble metal layer; partially filling the at least one opening with the Cu containing liner layer; and completely filling the at least one opening with electrical-chemical Cu plating. The forming a Cu containing liner layer is being compatible with PVD technique. In one particular embodiment, the partially filling the at one opening with the Cu containing liner layer includes thermal treating, heating, and reflowing of the Cu containing layer in an hydrogen-containing ambient. The thermal treating is performed at a temperature from about 100° C. to about 450° C. The hydrogen-containing ambient includes from about 2 to about 100% hydrogen.

Other features of the presently disclosed structure and method of forming interconnect structures will become apparent from the following detailed description taken in conjunction with the accompanying drawing, which illustrate, by way of example, the presently disclosed structure and method.

### BRIEF DESCRIPTION OF THE DRAWINGS

The features of the presently disclosed structure and method of forming interconnect structures will be described hereinbelow with references to the figures, wherein:

FIGS. 1-7 illustrate simplified cross-sectional views of progressive stages of a method of forming interconnect structures, in accordance with one embodiment of the present disclosure; and

FIG. 8A is an exemplary flow diagram illustrating a method of forming an interconnect structure, in accordance with one embodiment of the present disclosure.

FIG. 8B is an exemplary flow diagram illustrating a method of forming an interconnect structure, in accordance with another embodiment of the present disclosure.

### DETAILED DESCRIPTION

Referring now to the drawing figures, wherein like references numerals identify identical or corresponding elements, an embodiment of the presently disclosed method of forming an improved interconnect structure, will be disclosed in detail. In the following description, numerous specific details are set forth, such as particular structures, components, materials, dimensions, processing steps and techniques, in order to provide a thorough understanding of the present invention. However, it will be appreciated by one skilled in the art that the invention may be practiced without these specific details. In other instances, well-known structures or processing steps have not been described in detail to avoid obscuring the invention. Thus, the materials described herein are employed to illustrate the invention in one application and should not be construed as limiting.

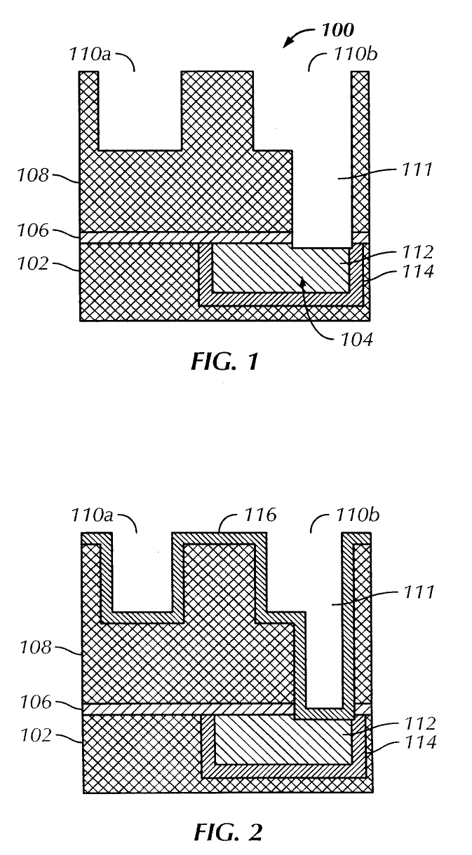

FIGS. 1-7 illustrate a structure and method of forming interconnect structures. In particular, these figures illustrate new and improved interconnect structures having a void-free copper fill and a method of forming a void free copper filled features. In one embodiment, the interconnect structure includes a patterned dielectric material and at least one Cu-containing conductive material having an upper surface embedded within the dielectric material; and a diffusion barrier and a noble metal liner separating the patterned dielectric material from the Cu-containing conductive material. The Cu-containing conductive material includes uniform impurity. In addition, the Cu-containing conductive material includes Sulfur having impurity less than about 100 pp, Carbon having impurity less than about 10 ppm and Chlorine having impurity less than about 10 ppm.

With initial reference to FIG. 1, an interconnect structure is illustrated and is designated generally as interconnect structure 100. Interconnect structure 100 includes generally a first insulating layer 102 (e.g. dielectric layer) formed on a base semiconductor substrate (not shown) and containing therewithin an interconnect element 104. A dielectric capping layer 106 is provided over first insulating layer 102 and interconnect element 104. In one embodiment, dielectric capping layer 106 includes a thickness ranging from about 15 nm to about 55 nm. A second insulating layer 108 is disposed on the upper surface of dielectric capping layer 106. A hard mask layer (not shown) is deposited on a top surface of second insulating layer 108 for forming interconnect openings 110A and 110B using conventional patterning techniques. Interconnect openings 110A and 110B are etched and formed in second dielectric layer 108 using well known etching methods, such as, for example, reactive ion etch (RIE). Interconnect opening 110A often refers to a trench feature, and interconnect opening 110B includes a trench feature and a contact via feature 111 extending through second dielectric layer 108 and dielectric capping layer 106 for exposing a portion of interconnect element 104.

In one embodiment, first insulating layer 102 is an interlayer dielectric which includes a dielectric constant, k, of about 4.0 or less and a thickness ranging from about 200 nm to about 450 nm. Insulating layer 102 may include any interlevel or intralevel dielectric, and may be porous or non-porous. Suitable materials include, but are not limited to, SiN, SiO2, Si3N4, SiCOH, SiLK (a polyarylene ether available from Dow Chemical Corporation), JSR (a spin-on silicon-carbon contained polymer material available from JSR corporation), silesquioxanes, C doped oxides (i.e. organosilicates) that include atoms of Si, C, O, and/or H, thermosetting polyarylene ethers, etc. or layers thereof. It is understood, however, that other materials having different dielectric constant and/or thickness may be employed. Second insulating layer 108 may include the same or different dielectric material as that of first dielectric material 102. Moreover, the processing techniques and thickness ranges described hereinabove with respect to first insulating layer 102 are also applicable to second insulating layer 108.

Interconnect element 104 is formed using conventional deposition techniques. Interconnect element 104 includes a conductive metal 112 and a highly resistive diffusion barrier 114 to prevent conductive metal 112 from diffusing. Diffusion barrier 114 is deposited using atomic layer deposition (ALD), or alternatively, a chemical vapor deposition (CVD) or physical vapor deposition (PVD) may be used. In one embodiment, diffusion barrier 114 includes a thickness ranging from about 1 nm to about 40 nm. Conductive metal 112 may be selected from a material including, for example, Cu, Al, W, their alloys, and any suitable conductive material. Highly resistive diffusion barrier 114 may be selected from a material including Ta, TaN, TiN, Ru, Ru(Ta), Ru(TaN), W, WN, or any other barrier material.

Dielectric capping layer 106 is formed through conventional deposition processes, such as, for example, CVD, ALD, plasma enhanced chemical vapor deposition (PECVD), etc. Dielectric capping layer 106 may include any of several materials well known in the art, for example, Si3N4, SiC, SiO2, and SiC (N, H) (i.e., nitrogen or hydrogen doped silicon carbide), etc.

With reference to FIG. 2, a diffusion barrier 116 is deposited over the surface of structure 100 using conventional deposition techniques, such as, for example, ALD, CVD or PVD. In one embodiment, diffusion barrier 116 includes the same or different material as that of diffusion barrier 114. Moreover, the processing techniques and thickness ranges described hereinabove with respect to diffusion barrier 114 are also applicable to diffusion barrier 116. In one particular embodiment, diffusion barrier 116 includes a noble metal liner selected from a material including Ru, Ir, Co, Pt, Rh, Ni, Pd, or any other suitable noble metal.

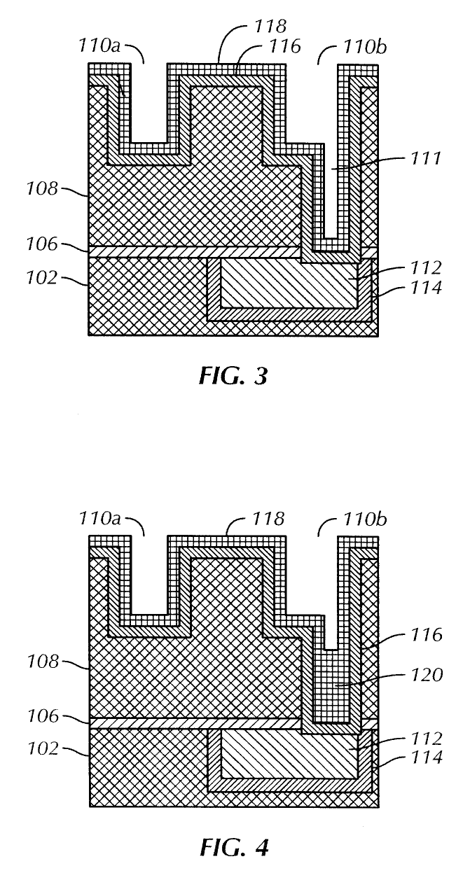

With reference to FIG. 3, overlaying diffusion barrier 116 is a seed layer of copper 118. Seed layer 118 is adapted for, inter alia, improving the adhesion of the copper fill to barrier layer 116, in a manner described in detailed hereinbelow. Seed layer 118 is deposited using, for example, high purity PVD deposition technique. Other deposition methods include ion-deposition sputtering techniques designed to maximize the copper <111> crystallographic content of the seed layer 118. Seed layer 18 includes copper and any suitable copper alloys. In one embodiment, seed layer 118 includes a thickness ranging from about 4 nm to about 100 nm. In particular, seed layer 118 was deposited via PVD technique, and the Cu deposition target contains impurities C<a 10 ppm, S<10 ppm, and Cl<10 ppm.

With reference to FIG. 4, a Cu re-flow process is carried out at about 200 C to about 300 C in a hydrogen containing environment. In particular, the deposited Cu liner layer 118 at the field area re-flows into the patterned features, 110A and 110B. In one embodiment, as shown in FIG. 4, the trench feature 110A and the via feature 111 in 110B are partially filled with the Cu containing material 118 post the re-flowing process. Since the deposited seed layer 118 comes from a high purity target, the partially Cu filled trench feature 110A and the via feature 111 in 110B contains C<10 ppm, Cl<10 ppm, and S<10 ppm.

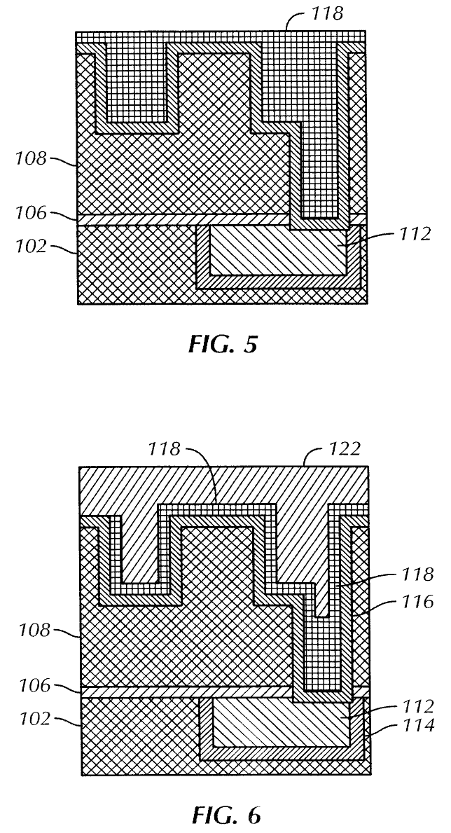

With reference to FIG. 5, the patterned features 110A and 110B are completely filled with the Cu containing material 118. In this embodiment, repeat processes of the mentioned seed layer 118 deposition, FIG. 3, and the mentioned thermal re-flow process, FIG. 4, may required to completely fill the patterned features 110A and 110B. Since the deposited seed layer 118 comes from a high purity target, the completely Cu filled trench feature 110A and the via feature 120 in 110B contains C<10 ppm, Cl<10 ppm, and S<10 ppm.

With reference to FIG. 6, in conjunction with FIG. 4, a second embodiment of the present invention is described. In this embodiment, an electro-chemical plating (ECP) process is used to complete filling in the patterned features 110A and 110B with copper 122. In using ECP, the plating bath dissolves the surface of copper seed layer 118, producing a fresh clean surface onto which copper fill layer 122 can grow. This provides reduced resistivity in the copper fill as a whole (providing for the removal of any copper oxide which may be present) and assists in obtaining the desired <111> crystallographic content in the copper fill. In this particular embodiment, the electrical-chemical copper plating is performed in a copper containing bath having Sulfur containing impurity higher than about 10 ppm, Carbon containing impurity higher than about 10 ppm, and Chlorine, containing impurity higher than about 10 ppm. The resulting Cu material 122 also contains high impurities, S>10 ppm, C>10 ppm, and Cl>10 ppm.

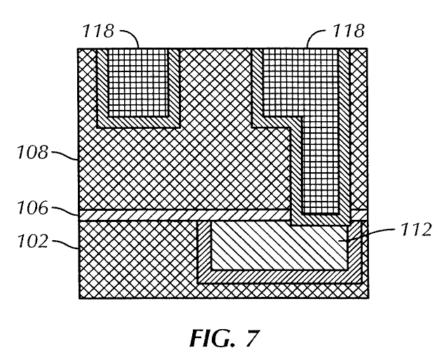

FIG. 7 illustrates the structure of FIG. 5 after planarization, such as, for example, chemical mechanical planarization.

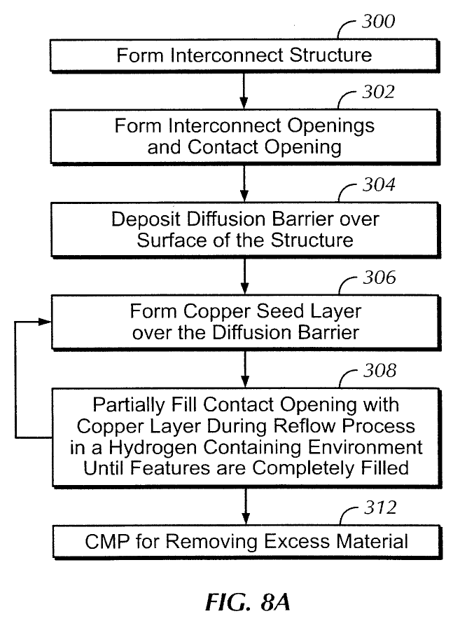

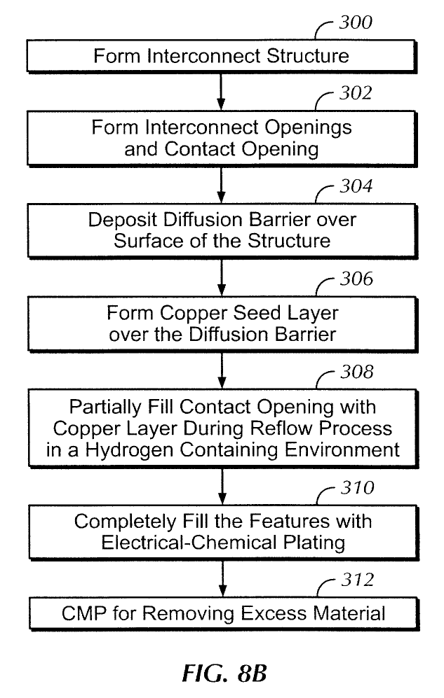

With reference to FIGS. 8A and 8B, in conjunction with FIGS. 1-7, two flow diagrams of an exemplary method of forming a high purity Cu structure for interconnect applications, in accordance with the present disclosure, are illustrated. Initially, at step 300, an interconnect structure 100 is formed including a first insulating layer 102 formed on a base semiconductor substrate (not shown) and having therewithin an interconnect element 104, a dielectric capping layer 106 formed over first insulating layer 102 and a second insulating layer 108 formed over dielectric capping layer 106, as discussed hereinabove. In accordance with the present disclosure, at step 302, interconnect openings 110A and 110B are formed in second insulating layer 108, where interconnect opening 110A often refers to a trench feature and 110B includes a contact opening 111 for exposing a portion of interconnect element 104. At step 304, a diffusion barrier 116 is deposited over the surface of the structure. At step 306, a copper seed layer 118 is formed over diffusion barrier 116. At step 308, contact opening 111 is partially filled with a copper layer 118 during a copper reflow process in a hydrogen containing environment. It's optional to go back steps 306 and 308 several times for completely filling the features 110A and 110B with the copper seed 118, FIG. 8B. Alternatively, electromechanical plating is formed after performing the copper reflow, FIG. 8A. Finally, at step 312, a CMP is performed to remove any excess material.

It will be understood that numerous modifications and changes in form and detail may be made to the embodiments of the presently disclosed structure and method of forming a high purity Cu structure for interconnect applications structures. It is contemplated that numerous other configuration of the interconnect structure may be formed, and the material of the structure and method may be selected from numerous materials other than those specifically disclosed. Therefore, the above description should not be construed as limiting the disclosed structure and method, but merely as exemplification of the various embodiments thereof. Those skilled in the art will envisioned numerous modifications within the scope of the present disclosure as defined by the claims appended hereto. Having thus complied with the details and particularity required by the patent laws, what is claimed and desired protected is set forth in the appended claims.

What is claimed is:

1. An interconnect structure comprising:
a patterned dielectric material and at least one Cu-containing conductive material having an upper surface embedded within said dielectric material; and
a diffusion barrier and a noble metal liner separating said patterned dielectric material from said at least one Cu-containing conductive material;
wherein said Cu-containing conductive material having uniform impurity.

2. The interconnect structure of claim 1, wherein said Cu-containing conductive material having Sulfur containing impurity less than about 10 ppm, Carbon containing impurity less than about 10 ppm, and Chlorine, containing impurity less than about 10 ppm.

3. The interconnect structure of claim 1, wherein said diffusion barrier being formed on said patterned dielectric layer, and said noble metal liner being formed on said diffusion barrier.

4. The interconnect structure of claim 1, wherein said diffusion barrier is selected from the group consisting of Ta(N), Ti(N), W(N) and alloys thereof.

5. The interconnect structure of claim 1, wherein said noble metal liner is selected from the group consisting of Ru, Ir, Rh, Pt, Co and alloys thereof.

6. The interconnect structure of claim 1, wherein an upper surface of said at least one Cu-containing conductive material is substantially coplanar with said surface layer of said dielectric material.

7. The interconnect structure of claim 1, further comprising a dielectric capping layer located atop said dielectric material and said at least one Cu-containing conductive material.

8. An interconnect structure comprising:
a patterned dielectric material and at least one Cu-containing conductive material having an upper surface embedded within said dielectric material; and
a diffusion barrier and a noble metal liner separating said patterned dielectric material from said at least one Cu-containing conductive material; and
said Cu-containing conductive material having NON-uniform impurity.

9. The interconnect structure of claim 1, wherein said Cu-containing conductive material having higher impurity levels at top part of the structure, but lower impurity levels at bottom part of the structure.

10. The interconnect structure of claim 9, wherein said top part of said Cu-containing conductive material having Sulfur containing impurity higher than about 10 ppm, Carbon containing impurity higher than 10 ppm, and Chlorine, containing impurity higher than about 10 ppm.

11. The interconnect structure of claim 9, wherein said bottom part of said Cu-containing conductive material having Sulfur containing impurity less than about 10 ppm, Carbon containing impurity less than about 10 ppm, and Chlorine, containing impurity less than about 10 ppm.

12. The interconnect structure of claim 8 further comprising a dielectric capping layer located atop said dielectric material and said at least one Cu-containing conductive material.

13. A method of fabricating an interconnect structure comprising:
providing an initial interconnect structure that includes a dielectric having at least one opening;
forming a diffusion barrier layer on all exposed surfaces;
forming a noble metal layer on said diffusion barrier layer;
forming a Cu containing layer on said noble metal layer; and
completely filling said at least one opening with said Cu containing layer.

14. The method of claim 13, wherein said providing said initial interconnect structure includes a via opening, a line opening, and both a via and a line opening.

15. The method of claim 13, wherein said forming a diffusion barrier layer and said forming a noble metal layer are being compatible with PVD, CVD, and ALD techniques.

16. The method of claim 13, wherein said forming a Cu containing layer is being compatible with PVD technique.

17. The method of claim 16, wherein a Cu containing target used for said PVD deposition technique contains Sulfur containing impurity less than about 10 ppm, Carbon containing impurity less than 10 ppm, and Chlorine, containing impurity less than about 10 ppm.

18. The method of claim 13, wherein said completely filling said at least one opening with said Cu containing layer includes thermal treating, heating, and reflowing of said Cu containing layer in an hydrogen-containing ambient.

19. The method of claim 18, wherein said thermal treating is performed at a temperature from about 100° C. to about 450° C.

20. The method of claim 18, wherein said hydrogen-containing ambient includes from about 2 to about 100% hydrogen.

21. A method of fabricating an interconnect structure comprising:
providing an initial interconnect structure that includes a dielectric having at least one opening;
forming a diffusion barrier layer on all exposed surfaces;
forming a noble metal layer on said diffusion barrier layer;
forming a Cu containing layer on said noble metal layer;
partially filling said at least one opening with said Cu containing layer; and
completely filling said at least one opening with electrical-chemical Cu plating.

22. The method of claim 21, wherein said forming a Cu containing layer is being compatible with PVD technique.

23. The method of claim 21, wherein said partially filling said at one opening with said Cu containing layer includes thermal treating, heating, and reflowing of said Cu containing layer in an hydrogen-containing ambient.

24. The method of claim 23, wherein said thermal treating is performed at a temperature from about 100° C. to about 450° C.

25. The method of claim 23, wherein said hydrogen-containing ambient includes from about 2 to about 100% hydrogen.
